(19) United States
(12) Patent Application Publication
(10) Pub. No.: US 2008/0091998 A1
(43) Pub. Date: Apr. 17, 2008

(54) Partial Enhanced Scan Method for Reducing Volume of Delay Test Patterns

(75) Inventor: Seongmoon Wang, Plainsboro, NJ (US)

Correspondence Address: NEC LABORATORIES AMERICA, INC., 4 INDEPENDENCE WAY, Suite 200, PRINCETON, NJ, 08540, US

(73) Assignee: NEC LABORATORIES AMERICA, INC., Princeton, NJ (US)

(21) Appl. No.: 11/851,137

(22) Filed: Sep. 6, 2007

Related U.S. Application Data
(60) Provisional application No. 60/829,183, filed on Oct. 12, 2006.

(51) Int. Cl. G01R 31/3183

(52) U.S. Cl. 714/729; 714/E11.002

(57) ABSTRACT

A method includes selecting at least one regular scan cell that is replaced with a corresponding one of an enhanced scan cell in a scan chain for scan based delay testing of the digital circuit, controlling the enhanced scan cell with a skewed load approach, and controlling regular scan cells of the scan chain with a broadside approach. More specifically, this reduces test sequence lengths and achieves higher delay fault coverage, without having to pay high cost to drive all scan cells by the skewed load approach, which requires a faster switching than the broadside approach. No additional pins are required for driving enhanced scan cells because the drive signal for switching the enhanced scan cells is derived from the signal for driving the regular scan cells.

This application claims the benefit of U.S. Provisional Application No. 60/829,183, entitled “Low overhead partial enhanced scan technique for compact and high fault coverage transition delay test patterns”, filed on Oct. 12, 2006, the contents of which is incorporated by reference herein.

### BACKGROUND OF THE INVENTION

The present invention relates generally to testing of chips for performance related failures, and, more particularly, to a method that uses enhanced scan cells to reduce volume of delay test patterns and improve delay fault coverage for digital circuits.

The following works by others are mentioned in the application and referred to by their associated reference:
[1] S. Wang, X. Liu, and S. T. Chakradhar. Hybrid Delay Scan: A Low Hardware Overhead Scan-Based Delay Test Technique for High Fault Coverage and Compact Test Sets. In Proceedings Design Automation and Test in Europe Conference and Exhibition, pages 1296-1301, February 2004.
[2] N. Ahmed, C. P. Ravikumar, M. Tehranipoor, and J. Plusquellic. At-Speed Transition Fault Testing with Low Speed Scan Enable. In Proceedings VLSI Testing Symposium, pages 42-47, May 2005.
[3] N. Ahmed, M. Tehranipoor, and C. P. Ravikumar. Enhanced Launch-Off-Capture Transition Fault Testing. In Proceedings IEEE International Test Conference, pages 246-255, November 2005.
[4] N. Devtaprasanna, A. Gunda, P. Krishnamurthy, S. M. Reddy, and I. Pomeranz. Methods for Improving Transition Delay Fault Coverage Using Broadside Tests. In Proceedings IEEE International Test Conference, pages 256-265, November 2005.

With ever decreasing geometry sizes and increasing clock speeds, ascertaining correct operation of digital circuits at a desired speed is becoming a necessity rather than an option to maintain product quality level. The scan-based delay testing where test patterns are generated by an automatic test pattern generator (ATPG) for designs that involve scan chains is increasingly used as a cost efficient alternative to the at-speed functional pattern approach to test large scale chips for performance-related failures.

Detecting a delay fault normally requires the application of a pair of test patterns: the first pattern, called initialization pattern, initializes the targeted faulty circuit line to a desired value and the second pattern, called launch pattern, launches a transition at the circuit line and propagates the fault effect to primary output(s) and/or scan cell(s). Two different approaches, which differ in the way of applying the second pattern of each pattern pair, are used to apply two-pattern tests to standard scan designs. In the first approach, referred to as the skewed-load or launch-off-shift approach, the second pattern is obtained by shifting in the first pattern by one scan cell. In the second approach, referred to as the broadside or launch-off-capture, the second pattern is obtained from the circuit response to the first pattern. For most designs, test pattern sets generated by the skewed-load approach achieve higher fault coverage than those generated by the broadside approach. While test patterns for the skewed-load approach can be generated by a combinational ATPG, generating test patterns for the broadside requires a sequential ATPG. Further, sizes of test pattern sets generated by the skewed-load approach are also typically smaller than those generated by the broadside approach. However, since the skewed-load approach requires higher hardware overhead and longer design time, the broadside approach is more widely used in the industry.

The procedures of applying test pattern pairs to a standard scan design are illustrated with timing diagrams 10 of scan enable signal scan_en in FIG. 1. All scan cells are controlled by scan enable signal(s) to configure them into either their shift mode or normal mode. We assume that the scan chain is constructed with muxed scan type flip-flops (see diagram 40 FIG. 4(b)).

At the initialization clock edge, the initialization pattern of a pattern pair is fully loaded into the scan chain and applied to scan inputs in both the skewed-load and the broadside approach. The launch pattern is applied after the circuit under test (CUT) is stabilized from switching caused by applying the initialization pattern. In the skewed-load approach, scan_en stays at logic 1 until the launch clock is triggered. Hence the scan chain is shifted by one cell at the launch clock edge. In contrast, in the broadside approach, scan_en transitions to 0 before the launch clock is triggered. Note that the period between the initialization clock and the launch clock need not be at-speed cycle. Hence scan_en does not require at-speed switching capability when the broadside approach is used. On the other hand, the period between the launch clock and the capture clock must be an at-speed cycle to test delay faults. Since in the skewed-load approach, scan cells are configured from shift mode to capture mode in the at-speed clock cycle, scan_en need at-speed switching capability. Typically only one scan_en signal drives all scan cells in the circuit under test CUT. Hence scan_en should be driven by a sophisticated buffer tree or strong clock buffer. Such a design requirement is often too costly to meet. Furthermore, meeting such a strict timing requirement for the scan enable signal will result in longer design time.

Even though the broadside approach is cheaper to implement than the skewed-load approach, fault coverage achieved by the broadside approach is typically lower than that achieved by the skewed-load approach. Further, test pattern sets generated by the broadside approach are also typically larger than those generated by the skewed-load approach. In order to generate two pattern tests by the broadside approach, a sequential ATPG that can handle two full time frames is required. On the other hand, test patterns for the skewed-load approach can be generated by a combinational ATPG with little modification. Hence, test generation time of the broadside approach is typically longer than that of the skewed-load approach. However due to high implementation cost and long design time described in the above paragraph, although the skewed-load approach has several advantages (higher fault coverage, smaller test pattern sets, and lower test generation cost) over the broadside approach, the broadside approach is the only choice of scan-based test method in many case.

Generating a transition test pattern pair for a full scan design by the broadside approach can be represented with a two time frame model of design. A two time frame model 20 of a sequential circuit that employs full scan is shown in FIG. 2. The circuit has h primary inputs, pi₁, pi₂, . . . , piₕ, m primary outputs, po₁, po₂, . . . , poₘ, n state inputs, si₁, si₂, . . . , siₙ, and also n state outputs, so₁, so₂, . . . , soₙ. Note that state outputs soᵢ, where i=1, 2, . . . , n, of the first time frame are connected to state inputs siᵢ of the second time frame. Hence the value at state output soᵢ in the initialization time frame is the same as the value at state input siᵢ in the launch time frame. In the real design, the pair of state output soᵢ and state input siᵢ are connected through a scan flip-flop Dᵢ to constitute a feedback loop.

The test cost is directly determined by the volume of test pattern set. Due to large test volume required to achieve satisfactory coverage, transition fault coverage is often compromised for acceptable test volume. In most compaction algorithms, don't cares in test patterns, play an important role in compacting test sets. Test compaction techniques can be classified as dynamic and static compaction according to when compaction of test patterns is performed. In dynamic compaction, which is performed during test generation, don't cares are specified to detect additional faults. Test patterns compacted by dynamic compaction are further reduced by static compaction after all test patterns are generated. Test patterns that have many don't cares can be easily merged with another test pattern by static compaction.

Recently, several low overhead scan-based delay testing techniques that can apply transition delay patterns via scan have been proposed [1,2,3,4]. Wang et al. [1] proposed a hybrid method where a small set of scan cells are controlled by the skewed-load approach and the rest scan cells are controlled by the broadside approach. Experimental results show that it can reduce test set sizes and improve transition delay fault coverage of the broadside approach. However, since it requires special ATPG algorithms, no existing commercial ATPG tools can be used to generate test patterns. Ahmed et al. proposed a technique that generates multiple local fast scan enable signals [2]. Fast scan enable signals are generated by scan cells from global scan enable signal. A technique that requires no fast switching control signal for scan cells is proposed by Devtaprasanna et al. [4]. However, this technique requires a special ATPG like [1]. Ahmed et al. [3] proposed an enhanced launch-off-capture technique where a part of scan cells are not configured into their capture mode in each launch and capture cycles and stay in their shift mode. To optimize the best results by this technique, the ATPG should understand the proposed technique.

Accordingly, there is a need for a new scan based-delay testing technique that combines advantages of the skewed-load and broadside approaches.

### SUMMARY OF THE INVENTION

In accordance with the invention, a method includes selecting at least one regular scan cell that is replaced with a corresponding one of an enhanced scan cell in a scan chain for scan based delay testing of the digital circuit, controlling the enhanced scan cell with a skewed load approach, and controlling regular scan cells of the scan chain with a broadside approach. More specifically, this reduces test sequence lengths and achieves higher delay fault coverage, without having to pay high cost to drive all scan cells by the skewed load approach, which requires a faster switching than the broadside approach. No additional pins are required for driving enhanced scan cells because the drive signal for switching the enhanced scan cells is derived from the signal for driving the regular scan cells.

In another aspect of the invention, an apparatus includes a scan chain for scan based delay testing of a digital circuit having a number of regular scan cells controlled by broadside switching and at least one enhanced scan cell controlled by skewed-load switching. The skewed-load switching of the enhanced scan cells is faster than the broadside switching of the regular scan cells. Preferably, a drive signal for controlling the at least one enhanced scan cell is derived from a drive signal for controlling the regular scan cells. In an exemplary embodiment, the enhanced scan cell includes a master flip-flop and a slave flip-flop connected through a multiplexer for selecting an input source to the master flip-flop between an input and an output of the slave flip-flop with the output of the master flip-flop directly driving a state input. The model of enhanced scan cell for automatic test pattern generation applications which allows any ATPG tool be used to generate test patterns for the design with the present invention comprises a second multiplexer selectively enabled for selecting between the output of the master flip-flop and an output of the slave flip-flop.

### BRIEF DESCRIPTION OF DRAWINGS

These and other advantages of the invention will be apparent to those of ordinary skill in the art by reference to the following detailed description and the accompanying drawings.

FIG. 1 depicts timing diagrams for standard scan-delay testing with skewed load and broadside approaches for applying two-pattern tests to standard scan designs.

FIG. 2 depicts a two time frame model for representing generating a transition test pattern pair for a full scan design by the broadside approach of FIG. 1.

FIG. 3(a) depicts generating a transition delay pattern for a circuit without an enhanced chain.

FIG. 3(b) depicts generating a transition delay pattern for a circuit with an enhanced scan cell at siᵢ.

FIG. 4 depicts diagrams (a) of a scan chain that has an enhanced scan cell, (b) of a regular muxed scan cell (c) of an enhanced scan cell and (d) of waveforms of signals related to the enhanced scan cell, in accordance with the invention.

FIG. 5 depicts block diagrams of circuits for generating a skew_ld signal for driving the enhanced scan cell depicted in FIG. 4(a).

FIG. 6 is a block diagram of an enhanced scan cell for an automatic test pattern generator ATPG, in accordance with the invention.

FIG. 7 depicts part of a scan design for exemplary computing of usefulness measures of state inputs where enhanced scan cells, in accordance with the invention, are inserted into a standard scan chain.

FIG. 8 depicts a table of experimental results comparing the inventive enhanced scan cell technique with a pure broadside approach.

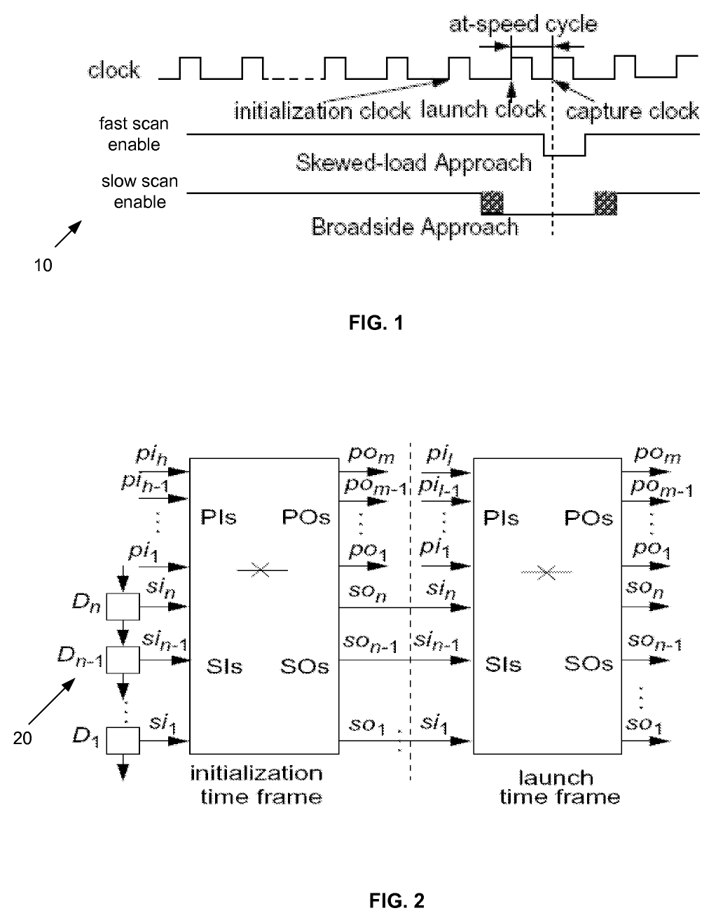

### DETAILED DESCRIPTION

The invention is a new scan based-delay testing technique that combines advantages of the skewed-load and broadside approaches. The inventive technique replaces a small set of regular scan cells by enhanced scan cells, which can hold two bits. The enhanced scan cells are controlled by the skewed-load approach and the regular scan cells controlled by the broadside approach. Sizes of test pattern sets generated by the proposed approach are smaller than those of test patterns generated by the traditional broadside approach. The proposed approach can achieve higher fault coverage than the traditional broadside approach. ATPG run time of the inventive hybrid approach is also shorter than that of the traditional broadside approach.

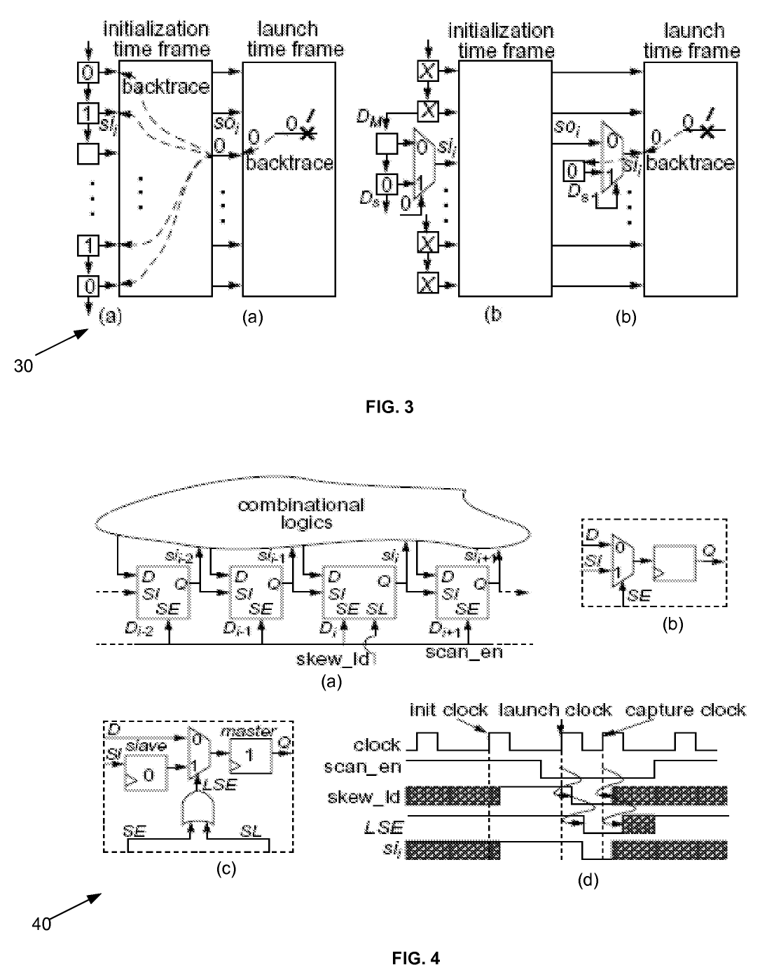

FIG. 3(a) of diagram 30 illustrates a process of setting line l to a 0 in the launch time frame in the standard broadside approach. Assume that setting line l to a 0 requires setting state input siᵢ to 0 in the launch time frame. Setting siᵢ to a 0 can be achieved by specifying several scan inputs in the initialization time frame as shown in FIG. 3(a). FIG. 3(b) illustrates setting the same line l to a 0 by the proposed method. Note that a multiplexer is inserted at state input siᵢ. The select input of the multiplexer is set to a 0 in the initial time frame and set to a 1 in the launch time frame. Hence the value stored in flip-flop D_{M} (D_{S}) is applied to state input siᵢ in the initialization (launch) cycle. Now, state input siᵢ can be set to a 0 in the launch time frame by assigning only one flip-flop D_{S} to a 0 without specifying any scan input in the initialization time frame. Hence line l can be set to a 0 in the launch time frame by specifying significantly fewer state inputs in the initialization time frame. Inserting an enhanced scan at siᵢ can also reduce ATPG run time since the ATPG process to specify siᵢ in the launch time frame through circuit lines in the initialization time frame is no longer needed. The function provided by flip-flops D_{M}, D_{S} and the multiplexer can be implemented by the proposed enhanced scan cell, which is described in the following.

FIG. 4(a) of diagram 40 shows a part of scan chain that contains an enhanced scan cell, FIG. 4(b) describes a regular muxed scan cell, and FIG. 4(c) describes the proposed enhanced scan cell. In the part of scan chain shown in FIG. 4(a), the enhanced scan cell is inserted at state input siᵢ. Scan enable pin SE of all scan cells, regular or enhanced, are driven by scan_en signal. A regular scan cell is configured into scan shift mode by setting SE to a 1 and capture mode by setting SE to a 0. Note that the enhanced scan cell inserted at siᵢ has one more control input, SL, which is driven by signal skew_ld, than the regular scan cell. The proposed enhanced scan cell consists of two constituent flip-flops, the master flip-flop and the slave flip-flop, which are connected through a multiplexer. The multiplexer selects an input source to the master flip-flop between input D and the output of the slave flip-flop. Note that the output of the master flip-flop directly drives state input siᵢ. Hence at the initialization cycle for each scan pattern pair, the master flip-flop is loaded with the value that state input siᵢ is assigned in the initialization pattern of the pattern pair. In the same cycle, the slave flip-flop is loaded with the value that will be applied to siᵢ in the next cycle (launch cycle). At the launch cycle edge, since LSE is set to a 1, the value stored in the slave flip-flop is loaded into the master flip-flop and applied to siᵢ. At the following cycle (capture cycle) edge, LSE is set to a 0 and the master flip-flop captures the response value that is at the D input. Note that since the multiplexer is inserted on the scan path, inserting enhanced scan cells does not entail any performance penalty.

FIG. 4(d) gives the timing diagrams of signals that are related to the operation of the enhance scan cell shown in FIG. 4(c). Consider applying a 1 to siᵢ in the initialization time frame and a 0 to siᵢ in the launch time frame. Assume that flip-flops of all scan cells are positive edge triggered for the sake of clarity of illustration without loss of generality. At the positive clock edge of the initialization clock, the master flip-flop is loaded with a 1 (hence a 1 is applied to state input siᵢ in the initialization cycle) and the slave flip-flop is loaded with a 0. Then scan_en signal is set to 0 to configure scan cells into capture mode to apply the launch pattern at the next clock (launch clock) edge. At the positive edge of the launch clock, all regular scan cells other than the enhanced scan cell capture the response to the test pattern applied in the initialization cycle and the launch pattern is applied to all state inputs except siᵢ. On the other hand, since skew_ld is 1 and hence LSE signal of the enhanced scan cell is 1 at the the positive edge of the launch clock, the master flip-flop in the enhanced scan cell is loaded with the value stored in the slave flip-flop, i.e., 0, instead of the value at the D input. Hence a 0 is applied to state siᵢ in the launch cycle. In the capture cycle, all scan cells including the enhanced cell are loaded with the response to the launch pattern.

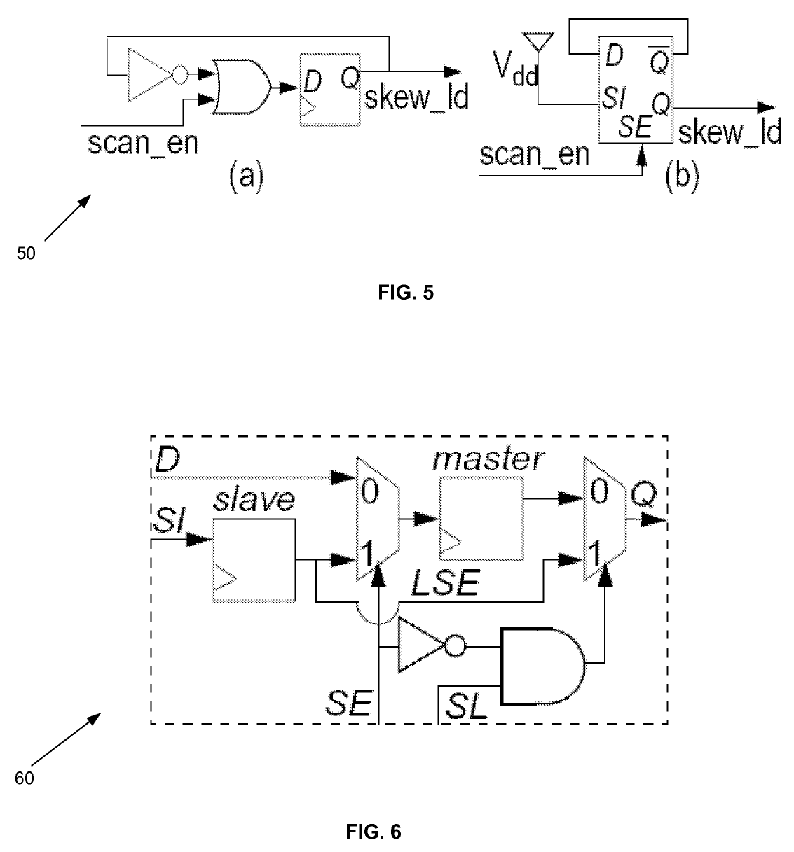

As FIG. 4(d) shows, skew_ld signal requires at-speed switching capability (skew_ld transitions from 1 to 0 in the cycle between the launch and the capture clock). In this paper, enhanced scan cells are inserted at only up to 2% of scan inputs in the circuit. In other words, skew_ld signal drives a very small number (2% or less) of scan cells. Hence, making skew_ld switch at-speed is a lot easier than making scan_en, which drives all the scan cells in the design, switch at-speed. skew_ld signal is internally generated with a very small circuit and hence no extra pin is required for skew_ld. skew_ld signal can be generated from scan_en as shown by the diagrams 50 in FIG. 5.

Enhanced scan cells can be inserted by simply replacing the regular scan cells that were already inserted by the regular scan insertion procedure. Most commercial ATPG tools do not support the proposed enhanced scan cell described in FIG. 4(c). Hence, we cannot directly generate transition delay test patterns for a design that has the proposed enhanced scan cells. However, this problem can be solved by using a separate library for the ATPG. In the library file for the ATPG tool, the real description for the enhanced scan cell (see FIG. 4(c) is replaced by the description shown by the diagram 60 in FIG. 6. Using a separate library for the ATPG is common in the industry. Note that the design (netlist) need not be modified at all. Replacing the cell description shown in FIG. 4(c) by the cell description shown in FIG. 6 is fairly easy. During ATPG process, the function of the enhanced cell shown in FIG. 6 is exactly same as that of the real enhanced scan cell shown in FIG. 4(c).

As mentioned above, we limit the number of enhanced scan cells inserted to only 2% or less of entire state inputs in the design. Since we insert only very small number of enhanced scan cells, it is necessary to insert enhanced scan cells at the best state inputs to maximize the effect of inserting enhanced scan cells, i.e., the enhancement of delay fault coverage and the reduction in the number of test patterns. In this paper, two different metrics, controllability measure and usefulness measure, are computed for each state inputs to select the best state inputs to insert enhanced scan cells.

As mentioned above, don't cares in test patterns play an important role in compacting test pattern sets. If setting state input siᵢ to a binary value v in the launch time frame requires specifying large number of state inputs in the initialization time frame, then inserting an enhanced scan cell at siᵢ can create large number of don't cares in test patterns that need to set siᵢ to v.

In this application, controllability costs are defined for every circuit lines in the initialization time frame. The controllability cost Cv(l) of circuit line l, where v=0 or 1, represents the minimum number of inputs that should be specified to set l to binary values v. Controllability costs are computed from inputs towards outputs in a recursive fashion. The controllability cost Cv(l) is the minimal number of inputs that need to be specified to set the line l to a desired value v. The controllability costs of line l are given by

$$C v ( l ) = \{ \begin{matrix}1 & if 1 is a primary or state input \\ \vert {⋃}_{∀ {l}_{j}} {I}_{{l}_{j}} & if v = {c}_{a} ⊕ {i}_{a} \\ {min}_{{l}_{j}} \{ C c ( {l}_{j} ) \} & if v = {c}_{a} ⊕ {i}_{a} ,\end{matrix} \qquad ( 1 )$$

where lⱼ are the inputs of the gate gₐ with output line l, ∪ denotes a set union operator, Iₗ_{ⱼ} is a set of state inputs that should be specified to set lⱼ to v, and cₐ and iₐ are the controlling value and inversion of gₐ, respectively. If a state output soᵢ has a very large controllability cost Cv(soᵢ), it means that the corresponding state input siᵢ can be set to v in the launch time by specifying large number of inputs in the initialization time frame when the pure broadside approach is used to generate test patterns. Hence inserting an enhanced scan cell at state siᵢ will add large number of don't cares in test patterns.

Assume that state output soᵢ has a very large 1 controllability measure, i.e., C1(soᵢ)□1. Then inserting an enhanced scan flip-flop at siᵢ can create large number of don't cares in the test patterns that require a 1 at siᵢ in their launch time frames. However, if only a very few faults require a 1 at state input siᵢ in the launch time frame for their detection, then even if C1(soᵢ)□1, inserting an enhanced scan cell at state input siᵢ will not be able to reduce overall test data volume significantly. In other words, in order to achieve significant reduction in the number of test patterns, state inputs where enhanced scan cells are inserted should be used in many test patterns.

In this application, additional measures, the 0 usefulness measure and the 1 usefulness measure, are defined to select state inputs that need to be specified in large number of test patterns. In order to detect a stuck-at-0 (stuck-at-1) fault f at signal line l, the fault should be activated by setting signal line l to a 1 (0), and the activated fault (called fault effect) should be propagated to at least one observation point, i.e., primary or state output. If either of the above two processes becomes unachievable when state input siᵢ is not controllable to v, where v=0 or 1, then the fault f is said to be affected by the uncontrollability of siᵢ to v. The 0 (1) usefulness measure of state input siᵢ, U0(siᵢ) (U1(siᵢ)), reflects the number of stuck-at faults whose detections are affected when state input siᵢ cannot be set to a 0 (1). Note that since we consider usefulness of specifying state inputs in the launch time frame, we can use stuck-at fault model instead of transition delay fault model; a stuck-at 0 (1) fault actually represents a STR (STF) fault. If large number of faults are affected by the uncontrollability of input siᵢ to v, then launch patterns of test pattern pairs for large number of faults will require specifying siᵢ to v. In other words, inserting an enhanced scan cell at state input siᵢ will add don't cares in many test patterns.

The procedure to compute the usefulness measures for state input siᵢ starts by assigning 0̅ to siᵢ first ( 0̅ denotes that state input siᵢ is uncontrollable to 0. Next 0̅ is propagated to internal lines according to known propagation rules: If an input of an AND (OR) gate g is assigned 1̅ ( 0̅), i.e., not controllable to a 1 (0), then the output of g is assigned 1̅ ( 0̅). Likewise, if an input of an NAND (NOR) gate g is assigned 1̅ ( 0̅), i.e., not controllable to a 1̅ ( 0̅ ), then the output of g is assigned 0̅ ( 1̅). Depending on the circuit structure and function, some signal lines will be assigned either 1̅ and 0̅ when the 0̅ at siᵢ is propagated. Then, we identify (stuck-at) faults that cannot be activated when state input siᵢ is not controllable to 0. If signal line lⱼ is assigned 0̅ ( 1̅), then the stuck-at 1 (0) fault at line lⱼ cannot be activated and hence is untestable if siᵢ is uncontrollable to 0. These faults are obviously affected by the uncontrollability of siᵢ to 0̅. Next, we identify the faults whose fault effects are blocked at one or more gates. In order to propagate a fault effect through a gate, all the inputs other than the input where the fault effect is present should be assigned the non-controlling value of the gate. (The controlling value c of a gate is the binary value that, when applied to any input of a gate, determines the output value of that gate independent of the values applied at the other inputs of the gate and the non-controlling value nc of the gate is the opposite value of the controlling value.) In other words, if input lⱼ of gate g is not controllable to the non-controlling value of gate g, i.e., input lⱼ is assigned n̅c̅, then no faults in the fanin cones of the other inputs of g can propagate through gate g.

The 0 usefulness measure of state input siᵢ, U0(siᵢ), is given by the sum of numbers of faults that cannot be activated and faults whose fault effects are blocked at at least one gate when siᵢ is not controllable to a 0. We repeat the same procedure to compute the 1 usefulness measure of state siᵢ, U1(siᵢ), by setting state input siᵢ to 1̅ and propagating 1̅ at siᵢ into internal circuit lines. Usefulness measures are computed for every state input in the circuit.

The faults whose fault effects are blocked when state input siᵢ is uncontrollable to a binary value v can be identified by traversing fanin cones of all gates where their fault effects are blocked. Since the number of affected faults is computed for every state input, computing usefulness measures for large designs can be expensive in terms of run time complexity. In order to reduce run time, we use fanout free regions (FFRs) rather than individual circuit lines. In the preprocessing step, we identify all FFRs in the circuit. Then for each FFR, we count the number of faults in the FFR and store the number at the output signal of the FFR. In addition to the number of faults, the output signal line of each FFR stores the pointers to all the input signals of the FFR. Hence the number of faults that are blocked can be identified by traversing much fewer signal lines since signal lines which are not the output or inputs of an FFR, need not be traversed. This can speed up the traversal process significantly.

### EXAMPLE 1

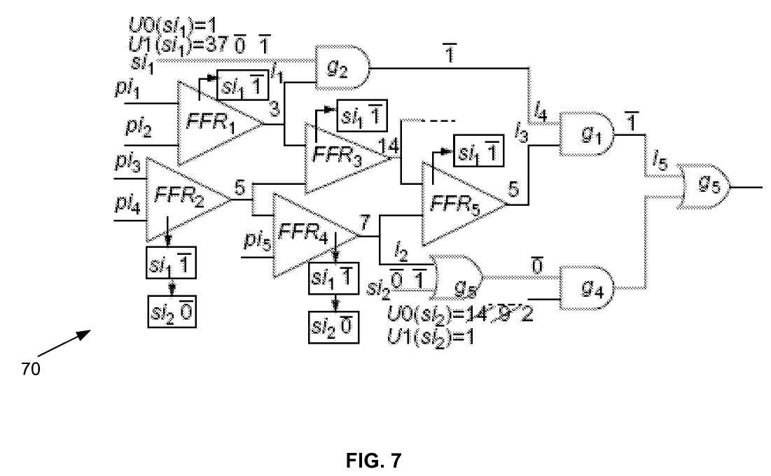

FIG. 7 shows a part of a scan design. Consider computing the 0 usefulness measure of state input si₁, i.e., U0(si₁). First, 0̅ is assigned to si₁. When si₁ is not controllable to 0, the output of AND gate g₂, which is the only gate driven by si₁, can still be set to 0 (by setting the other input l₁ to a 0). Hence 0̅ at si₁ does not propagate further down to the output of g₂ and U0(si₁)=1, i.e., only the stuck-at-1 (s-a-1) at si₁ is affected by the uncontrollability of si₁ to 0. Then, we compute U1(si₁) by first setting si₁ to 1̅. The stuck-at-0 at si₁ becomes untestable if si₁ is not controllable to a 1. When si₁ is not controllable to a 1, fault effects for the faults in the fanin cone of l₁ cannot propagate through g₂. Now we identify the number of faults in the fanin cone of l₁ by traversing from l₁ towards the inputs. Since fanout free region FFR₁, which is visited by the traversal, has 3 faults, 3 is added to U1(si₁). (The number shown at the output of each fanout free region, FFR₁, FFR₂, . . . , FFR₅, gives the number of faults in the fanout free region.) The visitation of FFR₁ is marked by adding si₁ 1̅ into the visitation list of FFR₁. 1̅ propagates to the output of g₂. Since the output of g₂, l₄, is not controllable to 1, the s-a-0 at l₄ is affected. Since the non-controlling value of g₁ is 1, the faults in the fanin cone of the other input of g₁, l₃, cannot propagate through g₁. If we use depth-first search, then fanout free regions FFR₅, FFR₃, FFR₄, and FFR₂ will be visited in the order. Note that since <si₁ 1̅> is already in the visitation list of FFR₁, FFR₁ is not visited again. Hence, U1(si₁)=5(FFR₂)+14(FFR₃)+7(FFR₄)+3(FFR₁)+5(FF₅)+1(si₁s-a-0)+1(l₄s-a-0)=36.

The gain function, which is used to select state inputs where enhanced scan cells are inserted, is computed for every state input using the controllability measures and the usefulness measures. The gain function G(siᵢ) for state input siᵢ is defined as follows:

G(siᵢ)=C0(soᵢ)×U0(siᵢ)+C1(soᵢ)×U1(siᵢ). (2)

Each time, the state input siₘ that has the largest G(siₘ) is selected and the regular scan cell already inserted at siₘ is replaced by an enhanced scan cell. This is repeated until S, which is pre-determined typically by designers, enhanced scan cells are inserted.

Let us revisit the scan design 70 shown in FIG. 7. Assume that si₁ has the largest gain function and hence an enhanced scan cell is inserted at si₁. Also assume that thanks to the enhanced scan cell inserted at si₁, specifying l₄ in the launch time frame can be achieved by specifying a very small number of inputs in the launch time frame. Suppose that setting si₂ to a 0 require specifying large number of inputs in the initial time frame. Note that the faults in fanout free regions FFR₂ and FFR₄ can propagate through either g₁ or g₄ for their detection. Since an enhanced scan cell is inserted at si₁, fault effects for faults in FFR₂ and FFR₄ can propagate through g₁ by setting l₄ a 1, which can now be achieved by specifying small number of inputs in the initialization time frame. Hence, inserting an enhanced scan cell at si₂ will not add many more don't cares in test patterns for faults in FFR₂ and FFR₄. Hence it is necessary to update usefulness measures of all scan inputs except the scan inputs whose regular scan cells are already replaced by enhanced scan cells after each enhanced scan cell is inserted. Usefulness measure can be updated very fast by using the visitation list that are maintained for each FFR.

### EXAMPLE 2

After an enhanced scan cell is inserted at si₁, all FFRs that are affected by either 1̅ or 0̅ at si₁ are traversed again (FFR₁, FFR₂, FFR₃, FFR₄, and FFR₅ are affected by 1̅ at si₁). When the update routine visits FFRⱼ, which has F faults in it, it checks all the elements in FFRⱼ's visitation list. If there is an element, <siᵢ v̅>, in FFRⱼ's visitation list and siᵢ's scan cell is still a regular scan cell (this means that the faults in FFRⱼ are affected also by the uncontrollability of si₁), then the update routine subtracts F (the number of faults in FFRⱼ) from Uv(siᵢ). For example, FFR₂ has two elements, <si₁ 1̅> and <si₂ 0̅>, and si₂'s scan cell is still a regular scan cell. Since FFR₂ has 5 faults, 5 is subtraced from U0(si₂) to make U0(si₂)=9. FFR₄, which has 7 faults, also has <si₂ 0̅> in its visitation list. Hence when traversing FFR₄'s visitation list, the update routin subtracts 7 again from U0(si₂) to make U0(si₂)=2.

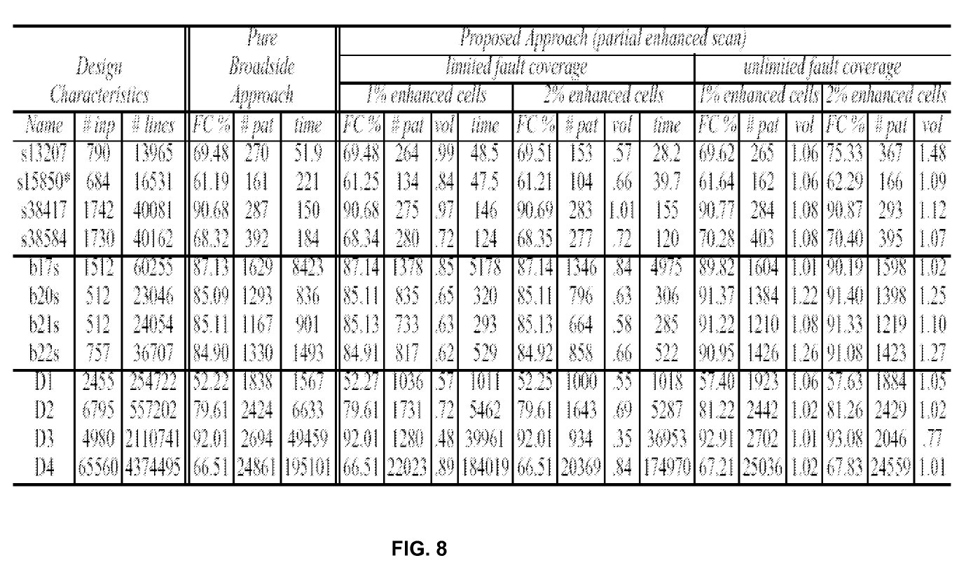

We implemented the proposed technique and conductedexperiments with large ISCAS 89 and ITC 99 benchmark circuitsand some industrial circuits. The experimental results are reported in the table of FIG. 8. Results obtained by the pure broadside approach (columns under the heading Pure BroadsideApproach) are compared with results obtained by using the inventive method (columns under the heading Proposed Approach (partial enhanced scan)). We conducted two different experiments for the proposed method: In the first experiment(columns under the heading limited fault coverage), we limited target fault coverage of the proposed method to the fault coverage achieved by the pure broadside approach. The main purpose of the first experiment is to see how much test volume can be reduced by the proposed method. In the second experiment (columns under the heading unlimited faultcoverage), we did not limit target fault coverage to see improvement of fault coverage by the proposed method. The column # inp shows the number of inputs in each circuit and the # lines shows the total number of signal lines in the circuit. For all cases, test patterns generated were highly compacted by both dynamic and static compaction.

The data shown under heading 1% enhanced cells (2% enhanced cells) give results for circuits where 1% (2%) of regular scan cells were replaced by enhanced scan cells. All test patterns including test patterns for the pure broadside approach were generated by our in-house transition delay ATPG tool. The columns FC % report transition delay fault coverage achieved while the columns # pat report the number of patterns generated by the ATPG. The columns vol give the test data volume of the proposed method, which is normalized to the test data volume of the pure broadside approach (1 means the test data volume of the proposed method is exactly same as that of the pure broadside approach). For the test data volume of the proposed method, we included test data for the added scan flip-flops (since each enhanced scan cell is comprised two scan flip-flops, if 1% enhanced scan cells are inserted, then the total number of scan flip-flops also increases by 1%). The columns time give ATPG run time in seconds.

The results clearly show that using the proposed method can reduce the number of test patterns. The number of test patterns and test data volume were significantly reduced by using the proposed method for most circuits except s13207 and s38417. It is notable that reduction in test data volume is larger in large industrial designs. Note that when 1% scan cells were replaced by enhanced scan cells, test data volume was reduced by 52% for D3 (when the target fault coverage of the proposed method was limited). When 2% scan cells were replaced by enhanced scan cells, test data volume for D3 was reduced by as much as 65%. Since the number of test patterns generated is reduced and time spent on justifying scan inputs in the launch time frame is also reduced, ATPG run time is significantly reduced. Note that when 2% enhanced scan cells were inserted, ATPG run time for s15850 was reduced from 221 seconds to 39.7 seconds, only 1/5.5. Reduction in ATPG run time is even larger for large industrial designs. Fault converge was enhanced by using the proposed method (see data under the heading unlimited fault coverage). Note that improvement of fault coverage is large for ITC 99 benchmark circuits that are hard to achieve high transition delay fault coverage. Inserting only 1% of enhanced scan cells was able to increase fault coverage for b22s by about 6%. This implies that the proposed method can be used to improve fault coverage for circuits for which the pure broadside approach cannot achieve desired fault coverage. Fault coverage achieved for the designs with proposed enhanced scan cells is always higher than that achieved by the pure broadside approach for every circuit. [Para 37] The inventive scan-based design-for-testability technique uses enhanced scan cells to reduce the volume of delay test patterns and improve delay fault coverage. The inventive technique replaces small number of regular scan cells by enhanced scan cells proposed in this paper. The proposed enhanced scan cell can hold two bits. The enhanced scan cells are controlled by the skewed-load approach and the rest of scan cells are controlled by the broadside approach. However, the inventive technique does not require custom design of scan enable signal, which controls scan cells during test application. Instead, an additional signal(s) is internally generated to control the enhanced scan cells in the skewed-load fashion. Inserting enhanced scan cells can increase don't cares in test patterns. Those don't cares can be utilized by dynamic and static compaction during ATPG process, thereby reducing test data volume. Further, inserting enhanced scan cells can reduce ATPG run time. Since only a small number of enhanced scan cells are inserted, hardware overhead for the proposed method is very low. The scan inputs where enhanced scan cells are inserted are selected by gain functions, which consist of controllability costs and usefulness measures. The controllability costs reflect the number of inputs that should be specified to set a signal line to a binary value and usefulness measures of a scan input reflect how many test patterns need to specify the scan input in the launch time frame. Unlike the teachings of Liu et al. in [1], which requires a special ATPG, a regular transition delay ATPG can be used to generate transition delay test patterns for a design that employs the proposed enhanced scan cells without modification.

Experimental results show that using the proposed method can reduce test data volume up to 65% and improve transition fault coverage up to about 6% when only a small number of regular scan cells are replaced by the proposed scan cells. Experimental results also show that significant reduction in ATPG run time can be achieved by using the proposed method.

In summary, the invention can achieve higher fault coverage than the traditional broadside approach. The invention can improve delay fault coverage and reduce test sizes without using the expensive skewed load approach, which require at-speed switching capability of scan enable signal. Any commercial tool ATPG tool that supports the broadside approach can be used without any modification. Hardware overhead incurred by the inventive method is very low. ATPG run time of the inventive approach is also shorter than that of the traditional broadside approach.

The present invention has been shown and described in what are considered to be the most practical and preferred embodiments. It is anticipated, however, that departures may be made there from and that obvious modifications will be implemented by those skilled in the art. It will be appreciated that those skilled in the art will be able to devise numerous arrangements and variations which, although not explicitly shown or described herein, embody the principles of the invention and are within their spirit and scope.

What is claimed is:

1. A method comprising the steps of:
selecting at least one regular scan cell to be replaced with a corresponding one of an enhanced scan cell in a scan chain for scan based delay testing of a digital circuit to reduce test sequence length and improve fault coverage,
controlling the enhanced scan cell with a skewed load approach, and
controlling regular scan cells of the scan chain with a broadside approach.

2. The method of claim 1, wherein a drive signal for switching the enhanced scan cells is derived from the signal for driving the regular scan cells without an extra input and output pin.

3. The method of claim 1, wherein the at least one regular scan cell replaced by the enhanced scan cell is selected to reduce test data volume.

4. The method of claim 1, wherein the at least one regular scan cell replaced by the enhanced scan cell is selected to change transition fault coverage.

5. The method of claim 1, wherein the step of selecting at least one regular scan cell to be replaced with a corresponding one of an enhanced scan cell enables automatic test pattern generator ATPG tools to increase don't cares in generated test patterns for the digital circuit and test pattern compaction on the don't cares for reducing test data volume.

6. The method of claim 3, wherein a number of the regular scan cells replaced by corresponding enhanced scan cells are selected responsive to number of inputs to be specified to set a signal line to a binary value.

7. The method of claim 3, wherein a number of the regular scan cells replaced by corresponding enhanced scan cells are selected responsive to how many test patterns need to specify a scan input in a launch time frame.

8. The method of claim 1, wherein the enhanced scan cell comprises a master flip-flop and a slave flip-flop connected through a multiplexer for selecting an input source to the master flip-flop between an input and an output of the slave flip-flop with the output of the master flip-flop directly driving a state input.

9. The method of claim 10, wherein a model of the enhanced scan cell for automatic test pattern generation applications comprises a second multiplexer selectively enabled for selecting between the output of the master flip-flop and an output of the slave flip-flop.

10. The method of claim 1, wherein the enhanced scan cell is a model for enabling use of any automatic test pattern generator tool to generate test patterns with reduced test sequence lengths and improved delay fault coverage.

11. The method of claim 1, wherein the step of selecting at least one regular scan cell to be replaced with a corresponding one of an enhanced scan cell comprises replacing those regular scan cells with the enhanced scan cells that can reduce test sequence lengths and improve delay fault coverage.

12. A apparatus comprising:
a scan chain for scan based delay testing of a digital circuit and having regular scan cells controlled by broadside switching and at least one enhanced scan cell controlled by skewed-load switching.

13. The apparatus of claim 12, wherein a drive signal for controlling the at least one enhanced scan cell is derived from a drive signal for controlling the regular scan cells.

14. The apparatus of claim 12, wherein enhanced scan cell comprises a master flip-flop and a slave flip-flop connected through a multiplexer for selecting an input source to the master flip-flop between an input and an output of the slave flip-flop with the output of the master flip-flop directly driving a state input.

15. The apparatus of claim 12, wherein drive signal for switching the enhanced scan cells is derived from the signal for driving the regular scan cells.

16. The apparatus of claim 12, wherein a number of the enhanced scan cells compared to a number of the regular scan cells is selected responsive to number of inputs to be specified to set a signal line to a binary value.

17. The apparatus of claim 12, wherein a number of the enhanced scan cells compared to a number of the regular scan cells are selected responsive to how many test patterns need to specify a scan input in a launch time frame.

18. The apparatus of claim 12, wherein a number of enhanced scan cells compared to a number of the regular scan cell is selected for increasing don't cares in test patterns for testing the digital circuit and employing compaction on the don't cares during testing pattern generation for reducing test data volume.

19. The apparatus of claim 12, wherein the enhanced scan cell is a model for enabling any automatic test pattern generator tool to generate test patterns with reduced test sequence lengths and improved delay fault coverage.

20. The apparatus of claim 12, wherein the enhanced scan cell replaces a corresponding one regular scan cell to reduce test sequence lengths and improve delay fault coverage.
